(19) United States
(12) Patent Application Publication
(10) Pub. No.: US 2025/0246513 A1
(43) Pub. Date: Jul. 31, 2025

(54) Hybrid Vapor Chamber Lid

(71) Applicant: Taiwan Semiconductor Manufacturing Company, Ltd., Hsin-Chu (TW)

(72) Inventors: Wei-Kong SHENG, Hsinchu (TW); Hsin Ting LIN, Hsinchu County (TW); Wensen HUNG, Hsinchu County (TW)

(21) Appl. No.: 18/671,460

(22) Filed: May 22, 2024

Related U.S. Application Data
(60) Provisional application No. 63/626,283, filed on Jan. 29, 2024.

(51) Int. Cl. H01L 23/427; H01L 21/52; H01L 23/00; H01L 23/367

(52) U.S. Cl. CPC H01L 23/427; H01L 21/52; H01L 23/367; H01L 24/32; H01L 2224/32245

(57) ABSTRACT

An exemplary heat-dissipating lid includes a thermally conductive casing having an upper plate and a lower plate, a first wick structure disposed on the lower plate and spanning an opening of the lower plate, and a hollow interior region disposed within the thermally conductive casing between the upper plate and the lower plate and between the upper plate and the first wick structure. The opening of the lower plate is configured to receive a second wick structure that is disposed on an integrated circuit (IC) die. In some embodiments, the heat-dissipating lid further includes thermally conductive columns disposed in the hollow interior region and between the upper plate and the lower plate. In some embodiments, the opening is a first opening, the thermally conductive casing further has mounting flanges extending from the lower plate, and the mounting flanges define a second opening for receiving the IC die.

This is a non-provisional application of and claims benefit of U.S. Provisional Patent Application Ser. No. 63/626,283, filed Jan. 29, 2024, the entire disclosure of which is incorporated herein by reference.

### BACKGROUND

Advanced integrated circuit (IC) packaging technologies have been explored to further reduce density and/or improve performance of ICs. For example, IC packaging has evolved, such that multiple ICs may be vertically stacked in three-dimensional (“3D”) packages or 2.5D packages (e.g., packages that implement an interposer). 3D packages and/or 2.5D packages may reduce footprints (e.g., by allowing for a greater number of components to be placed in a given chip area), reduce power consumption (e.g., by reducing lengths of signal interconnects), improve yield, reduce fabrication costs, or combinations thereof. However, as more components and/or more chips are packed into smaller areas, thermal dissipation and/or thermal management has become a key challenge facing IC packaging technologies.

### BRIEF DESCRIPTION OF THE DRAWINGS

The present disclosure is best understood from the following detailed description when read with the accompanying figures. It is emphasized that, in accordance with standard practice in the industry, various features are not drawn to scale and are used for illustration purposes only. For example, dimensions of the various features may be arbitrarily increased or decreased for clarity of discussion. It is also emphasized that the accompanying figures illustrate example embodiments and are therefore not to be considered limiting in scope.

FIG. 1A is a cross-sectional view of a package structure, in portion or entirety, that improves thermal management, according to various aspects of the present disclosure.

FIG. 1B is a cross-sectional view of a chip assembly, in portion or entirety, of the package structure of FIG. 1A according to various aspects of the present disclosure.

FIG. 1C is a cross-sectional view of a lid assembly, in portion or entirety, of the package structure of FIG. 1A according to various aspects of the present disclosure.

FIG. 2 is a top view of the chip assembly, in portion or entirety, of FIG. 1B according to various aspects of the present disclosure.

FIGS. 3-7 are cross-sectional views of the package structure of FIG. 1A, in portion or entirety, having different configurations, according to various aspects of the present disclosure.

FIG. 8 is a flow chart of a method, in portion or entirety, for forming a package structure, such as those described herein, according to various aspects of the present disclosure.

FIGS. 9A-9C, FIGS. 10A-10C, FIGS. 11A-11C, and FIGS. 12A-12C are cross-sectional views of different configurations of package structures, in portion or entirety, at various stages of the method of FIG. 8, according to various aspects of the present disclosure.

### DETAILED DESCRIPTION

The present disclosure relates generally to integrated circuit (IC) packaging, and more particularly, to lids for IC packages that improve thermal management thereof.

The following disclosure provides many different embodiments, or examples, for implementing different features of the invention. Specific examples of components and arrangements are described below to simplify the present disclosure. These are, of course, merely examples and are not intended to be limiting. For example, the formation of a first feature over or on a second feature in the description that follows may include embodiments in which the first feature and the second feature are formed in direct contact and may also include embodiments in which additional features may be formed between the first feature and the second feature, such that the first feature and the second feature may not be in direct contact. In addition, spatially relative terms, for example, “lower,” “upper,” “horizontal,” “vertical,” “above,” “over,” “below,” “beneath,” “up,” “down,” “top,” “bottom,” etc. as well as derivatives thereof (e.g., “horizontally,” “downwardly,” “upwardly,” etc.) are used for ease of the present disclosure to describe one feature's relationship to another feature. The spatially relative terms are intended to cover different orientations of the device including the features.

Furthermore, when a number or a range of numbers is described with “about,” “approximate,” “substantially,” and the like, the term is intended to encompass numbers that are within a reasonable range considering variations that inherently arise during manufacturing as understood by one of ordinary skill in the art. For example, the number or range of numbers encompasses a reasonable range including the number described, such as within +/−10% of the number described, based on known manufacturing tolerances associated with manufacturing a feature having a characteristic associated with the number. For example, a material layer having a thickness of “about 5 nm” can encompass a dimension range from 4.5 nm to 5.5 nm where manufacturing tolerances associated with depositing the material layer are known to be +/−10% by one of ordinary skill in the art. In another example, two features described as having “substantially the same” dimension and/or “substantially” oriented in a particular direction and/or configuration (e.g., “substantially parallel” or “substantially perpendicular”) encompasses dimension differences between the two features and/or slight orientation variances of the two features from the exact specified orientation that may arise inherently, but not intentionally, from manufacturing tolerances associated with fabricating the two features. Still further, the present disclosure may repeat reference numerals and/or letters in the various examples. This repetition is for the purpose of simplicity and clarity and does not in itself dictate a relationship between the various embodiments and/or configurations described herein.

To meet the continued demands of delivering advanced integrated circuits (ICs), IC dimensions (e.g., minimum IC feature size) have continued to be scaled down. Though downscaling of IC dimensions has boosted device performance and increased device density, the increased device density has also increased power density, which in turn has caused IC thermal management to become a key challenge in the development of advanced ICs and advanced IC packages. For example, an IC package may house an IC die (also referred to as a chip) between a lid and a package substrate, where the lid is configured and designed to dissipate heat from the IC die. Typically, the lid is attached to the IC die by a thermal interface material (TIM), such as a thermal grease and/or a thermal gel, to compensate for a coefficient of thermal expansion mismatch between the lid and the IC die. However, thermal conductivity of current TIMs is insufficient (i.e., lower than needed) for scaled, advanced IC packages, which has led to a thermal bottleneck in IC packaging, where overall temperature drops are limited by the TIM.

The present disclosure addresses such challenges by providing a hybrid vapor chamber lid that reduces thermal resistance between a lid and a die, thereby improving thermal dissipation in IC packages. The disclosed hybrid vapor chamber lid provides a direct cooling path on a lid-facing side of a die, such as a backside thereof, and eliminates TIM (and its thermal resistance) from between the die and the lid. Eliminating the TIM increases thermal conductivity between the die and the lid, thereby reducing thermal resistance therebetween. In some instances, the disclosed packages having a hybrid vapor chamber lid and die thermally coupled without TIM exhibit thermal resistance that about 22% to about 36% less than thermal resistance exhibited by packages that use TIM to thermally couple and/or attach a vapor chamber to a die. The disclosed packages thus exhibit better thermal conductivities than packages using TIM and thus may provide significantly improved heat dissipation. Different embodiments may have different advantages, and no particular advantage is required of any embodiment.

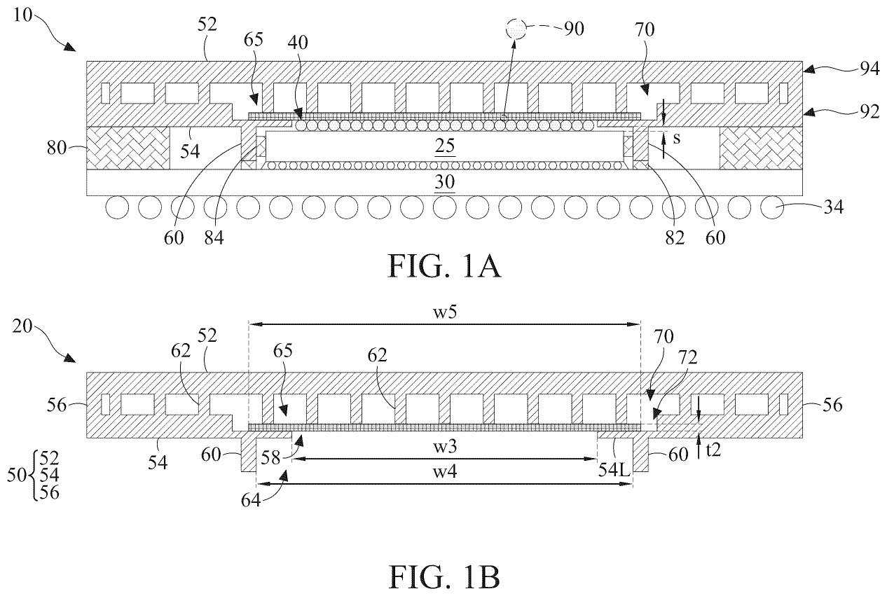

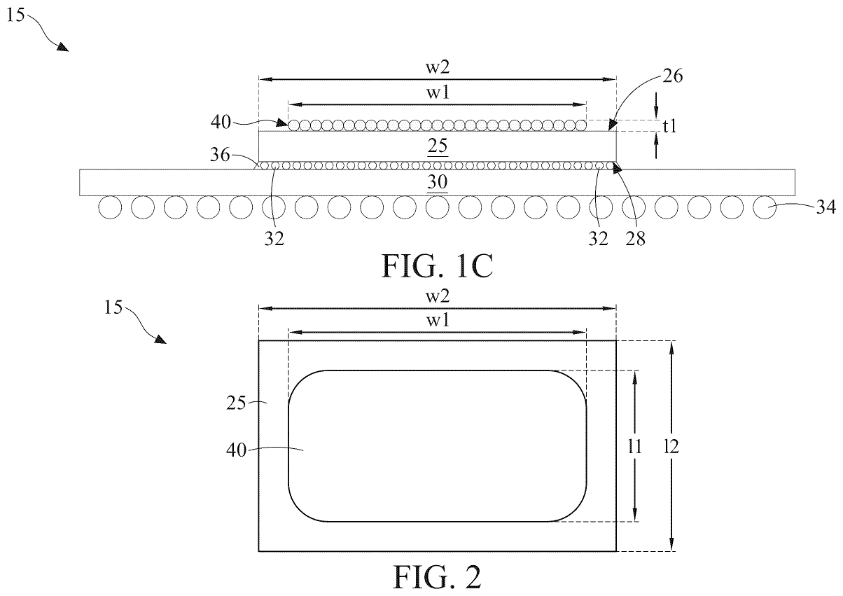

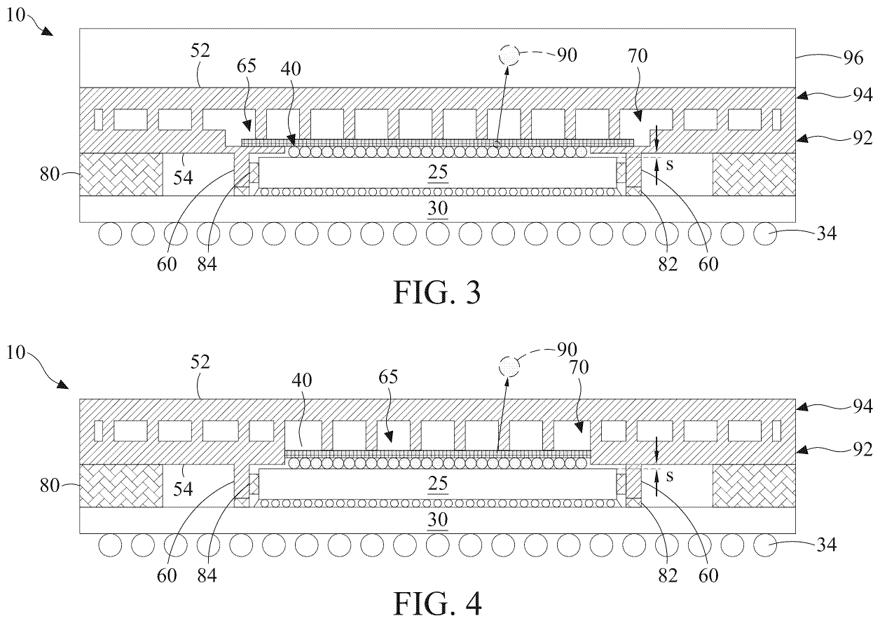

FIG. 1A is a cross-sectional view of a package structure 10, in portion or entirety, that improves thermal management (e.g., by reducing thermal resistance), according to various aspects of the present disclosure. Package structure 10 includes a die assembly 15 and a lid assembly 20. FIG. 1B is a cross-sectional view of die assembly 15, in portion or entirety, according to various aspects of the present disclosure. FIG. 1C is a cross-sectional view of lid assembly 20, in portion or entirety, according to various aspects of the present disclosure. FIG. 2 is a top view of a part of die assembly 15 according to various aspects of the present disclosure. FIGS. 3-7 are cross-sectional views of different configurations of package structure 100, in portion or entirety, according to various aspects of the present disclosure. FIGS. 1A-1C, FIG. 2, and FIGS. 3-7 are discussed concurrently herein for ease of description and understanding. FIGS. 1A-1C, FIG. 2, and FIGS. 3-7 have been simplified for the sake of clarity to better understand the inventive concepts of the present disclosure. Additional features may be added in package structure 10, die assembly 15, lid assembly 20, or combinations thereof, and some of the features described below may be replaced, modified, or eliminated in other embodiments of package structure 10, die assembly 15, lid assembly 20, or combinations thereof.

Die assembly 15 includes at least one die (also referred to as a chip), such as a die 25. Die 25 has a lid-facing side 26 (also referred to as a lid-facing surface) and a side 28 (also referred to as a surface) that is opposite lid-facing side 26. In some embodiments, lid-facing side 26 is a backside BS of die 25 and side 28 is a frontside FS of die 25. Die 25 includes at least one functional IC, such as an IC configured to perform a logic function, a memory function, a digital function, an analog function, a mixed signal function, a radio frequency (RF) function, an input/output (I/O) function, a communications function, a power management function, other function, or combinations thereof. In some embodiments, die 25 is a central processing unit (CPU). In some embodiments, die 25 is a graphics processing unit (GPU). In some embodiments, die 25 is a memory, such as a static random-access memory (SRAM). In some embodiments, such as in the depicted embodiment, die 25 is a system-on-chip (SoC), which generally refers to a single chip and/or monolithic die having multiple functions. In some embodiments, the SoC is a single chip having an entire system, such as a computer system, fabricated thereon. In some embodiments, die 25 is utilized for high performance computing (HPC) applications.

Die 25 is mounted on a package component 30. Package component 30 may be a cored package substrate, a coreless package substrate, an interposer, a printed circuit board (PCB), or the like. Package component 30 may include electrically conductive routing structures (e.g., formed of copper, aluminum, other metal, alloys thereof, or combinations thereof) embedded in dielectric material(s), and the electrically conductive routing structures may facilitate electrical connection of package component 30 with die 25, another package component, an external component/device, or combinations thereof. In some embodiments, package component 30 is a cored package substrate, which may include a core, such as a polyimide layer and/or glass-reinforced epoxy layer, sandwiched between two build-up layers, and each of the two build-up layers may include electrically conductive routing structures embedded in dielectric material(s). Through-vias may extend through the core to electrically connect the two build-up layers (e.g., electrically conductive routing structures thereof). In some embodiments, package component 30 is an interposer, such as a silicon substrate having through-vias (e.g., electrically conductive structures that extend through the silicon substrate) disposed therein. In some embodiments, package component 30 includes an interposer and redistribution layers (RDLs) formed over a top and/or a bottom of the interposer. The RDLs may include dielectric material(s) (e.g., polyimide, polybenzoxazole (PBO), benzocyclobutene (BCB), other suitable polymer-based material, or combinations thereof) having electrically conductive routing structures disposed therein, and the RDLs may electrically connect bond pads on one side of the interposer (e.g., a top side thereof having die 25 mounted thereto) to bond pads on another side of the interposer (e.g., a bottom side thereof, which may be mounted to another package component, such as a PCB). In some embodiments, the RDLs may electrically connect bond pads on a top side of the interposer, which may electrically connect die 25 to other dies of a chipset of package structure 10, such as where a chip set (multiple dies) are mounted on package component 30. In some embodiments, package component 30 is a PCB.

In some embodiments, die 25 is attached and/or bonded to package component 30 by connectors 32, and package component 30 may be attached and/or bonded to another component by connectors 34. Connectors 32 may electrically connect die 25 and package component 30, and connectors 34 may electrically connect package component 30 to another package component, such as a PCB, and/or external component/device. In some embodiments, connectors 32 are electrically conductive bumps, balls, pillars, or combinations thereof disposed on electrically conductive regions/pads of side 28 of die 25 (e.g., of a frontside interconnect structure thereof) and electrically conductive portions of die-facing side/surface of package component 30 (e.g., TSVs and/or electrically conductive routing structures thereof), and connectors 34 are electrically conductive bumps, balls, pillars, or combinations thereof disposed on electrically conductive portions of package component 30 (e.g., TSVs and/or electrically conductive routing structures thereof). Connectors 32 and connectors 34 include solder, copper, aluminum, gold, nickel, silver, palladium, tin, other suitable electrically conductive material, or combinations thereof. Connectors 32 and connectors 34 may be and/or include lead-free solder balls, solder balls, ball grid array (BGA) balls, balls and/or bumps formed by a controlled collapse chip technique (i.e., C4 bumps), microbumps, other types of electrically conductive bonding structures, or combinations thereof. In some embodiments, connectors 32 and connectors 34 are different types of connectors. For example, connectors 32 may be microbumps, and connectors 34 may be C4 bumps. In some embodiments, connectors 32 and connectors 34 are a same type of connector and may have the same or different sizes.

Connectors 32 may be disposed in an underfill 36. Underfill 36 may fill spaces between connectors 32, and underfill 36 may fill space between die 25 and package component 30. In some embodiments, underfill 36 includes an organic material, such as an epoxy-based material. In some embodiments, underfill 36 includes a material that improves mechanical reliability of die assembly 15, for example, by distributing stresses across a die-side surface of package component 30 rather than allowing such stresses to become concentrated in, for example, connectors 32. In some embodiments, underfill 36 includes a material that protects connectors 32 from moisture and/or contaminants. In embodiments where package component 30 is mounted to another package component and/or external component, connectors 34 may be disposed in an underfill, which may be the same or different than underfill 36.

In some embodiments, die assembly 15 may further include an encapsulant (also referred to as a molding and/or a molding compound), and die 25, connectors 32, underfill 36, or combinations thereof may be disposed in and/or covered by the encapsulant. For example, the encapsulant may circumferentially surround die 25 and/or other chips of die assembly 15. In some embodiments, the encapsulant is disposed on edges of die 25, a top of die 25, a bottom of die 25 (e.g., between die 25 and package component 30), or combinations thereof. The encapsulant may include an organic material, such as an epoxy-based material. In some embodiments, the encapsulant and underfill 36 have different material compositions. In some embodiments, the encapsulant and underfill 36 have a same material composition.

Die assembly 15 further includes a vapor chamber lid component, such as a primary wick 40, mounted on die 25. In the depicted embodiment, primary wick 40 is formed and/or disposed directly on and/or in lid-facing side 26 of die 25 (e.g., backside BS thereof). Primary wick 40 is thermally coupled to lid-facing side 26 to facilitate heat transfer from die 25 to lid assembly 20 via primary wick 40. Primary wick 40 is a thermally conductive, porous structure that may convey a working fluid by capillary action. Primary wick 40 is formed of a thermally conductive material, which may be copper, aluminum, other thermally conductive material, alloys thereof, or combinations thereof. Primary wick 40 may be a grooved wick, a sintered wick, a mesh wick, other wick type, or combinations thereof. In the depicted embodiment, primary wick 40 is formed of copper and/or copper alloy, and primary wick 40 is a patterned copper structure, such as a copper grooved wick, disposed on die 25.

In some embodiments, primary wick 40 is formed by depositing a copper-containing layer over lid-facing side 26 of die 25 (e.g., by physical vapor deposition (PVD) or chemical vapor deposition (CVD)) and patterning the copper-containing layer (e.g., by forming a patterned mask layer over the copper-containing layer, etching the copper-containing layer using the patterned mask layer as an etch mask, and removing the patterned mask layer after the etching). In some embodiments, primary wick 40 is formed by forming a patterned mask layer over lid-facing side 26 of die 25, depositing a copper-containing layer over the patterned mask layer (e.g., by PVD or CVD), where the copper-containing layer may fill openings in the patterned mask layer, and removing the patterned mask layer after the depositing. A planarization process may be performed on the copper-containing layer before removing the patterned mask layer, and the planarization process may stop upon reaching the patterned mask layer. In some embodiments, primary wick 40 is formed by forming a patterned mask layer over lid-facing side 26 of die 25, patterning a thermally conductive portion of die 25 to form a wick structure (e.g., by patterning a copper-containing layer forming at least a portion of lid-facing side 26 of die 25, which may have been deposited by PVD or CVD during fabrication of die 25), and removing the patterned mask layer after patterning the thermally conductive portion of die 25. The present disclosure contemplates various processes for forming primary wick 40 on lid-facing side 26.

To optimize heat dissipation, lateral dimensions of primary wick 40 are configured to provide primary wick 40 covering most, but not all, of lid-facing side 26 of die 25. For example, primary wick 40 covers at least 85% of lid-facing side 26 of die 25. In FIG. 1C and FIG. 2, primary wick 40 has a width w1 and a length l1, lid-facing side/surface 26 of die 25 has a width w2 and a length l2, width w1 is less than width w2, length l1 is less than length l2, and an area A1 of primary wick 40 (e.g., area A1=length l1×width w1) is about 85% to about 95% of an area A2 of lid-facing side 26 of die 25 (e.g., area A2=length l2×width w2) (i.e., 0.85*A2≤A1≤0.95*A2). A primary wick-to-die coverage less than 85% may [[provide disadvantage]], while a primary wick-to-die coverage greater than 95% may [[provide disadvantage]]. In the depicted embodiment, primary wick 40 is positioned on a central portion of lid-facing side 26, such that a perimeter of lid-facing side 26 is not covered by primary wick 40. Primary wick 40 also has a thickness t1 that is less than about 150 μm (e.g., about 10 μm to about 150 μm).

Lid assembly 20 includes a casing 50 having an upper plate 52 and a lower plate 54. In some embodiments, casing 50 may further include sidewall plates (e.g., sidewalls 56), and upper plate 52 may be connected to lower plate 54 by sidewalls 56. In some embodiments, upper plate 52 and lower plate 54 may be directly connected, sealed together around perimeters thereof, for example, by diffusion bonding. Lower plate 54 has an opening 58 that is configured to receive a die-mounted wick during package assembly, such as primary wick 40 mounted to die 25. For example, opening 58 has a width w3 that is greater than about width w1 (i.e., width w3≥width w1) to accommodate primary wick 40 during package assembly. The present disclosure contemplates various configurations of casing 50 and various configurations of upper plate 52, lower plate 54, sidewalls 56, and opening 58 of lower plate 54.

Lid assembly 20 may further include mounting flanges 60 and support pillars 62. Mounting flanges 60 are configured for securing lid assembly 20 to die assembly 15 (e.g., to package component 30 thereof). Mounting flanges 60 may extend from lower plate 54 and define an opening 64 that is configured to receive a die during package assembly, such as die 25. For example, opening 64 has a width w4 that is greater than width w2 (i.e., width w4>width w2) to accommodate die 25 during package assembly. Support pillars 62 are disposed and extend between upper plate 52 and lower plate 54. In some embodiments, support pillars 62 may be cylindrically shaped and thus be referred to as support columns. The present disclosure contemplates various configurations of mounting flanges 60 and support pillars 62.

Casing 50, upper plate 52, lower plate 54, sidewalls 56, mounting flanges 60, and support pillars 62 include a thermally conductive material, such as copper, aluminum, other material having high thermal conductivity, alloys thereof (e.g., copper tungsten (CuW), copper-silicon-carbide (CuSiC), aluminum-silicon-carbide (AlSiC), or combinations thereof), or combinations thereof. In some embodiments, upper plate 52, lower plate 54, sidewalls 56, mounting flanges 60, and support pillars 62 are formed of a same thermally conductive material. For example, casing 50 may be a copper-containing casing, an aluminum-containing casing, or a steel-containing casing, and upper plate 52, lower plate 54, sidewalls 56, mounting flanges 60, and support pillars 62 may include copper, aluminum, or steel, respectively. In some embodiments, upper plate 52, lower plate 54, sidewalls 56, mounting flanges 60, support pillars 62, or combinations thereof are formed of different thermally conductive materials.

Lid assembly 20 further includes a support wick 65 formed and/or disposed on lower plate 54. Support wick 65 spans opening 58 in lower plate 54, such that a chamber 70 (i.e., a hollow interior region and/or a cavity) of lid assembly 20 is enclosed and/or formed by support wick 65 and casing 50 (e.g., formed by inner walls/surfaces of upper plate 52, lower plate 54, sidewalls 56, or combinations thereof). Support wick 65 is thermally coupled to lower plate 54, and in some embodiments, support wick 65 may physically contact lower plate 54. In some embodiments, lower plate 54 may be configured with a recessed portion 72 that provides a ledge 54L, and support wick 65 may be disposed and/or mounted on ledge 54L. In such embodiments, a thickness of a perimeter portion of lower plate 54 may be different than (e.g., less than) a thickness of a central portion of lower plate 54 (i.e., a thickness of ledge 54L). In some embodiments, in a top view, ledge 54L may provide a wick support surface shaped as a circular ring, a square ring, an octagonal ring, a hexagonal ring, or other suitable shaped ring.

Support wick 65 is a thermally conductive, porous structure that may convey a working fluid by capillary action. Support wick 65 is formed of a thermally conductive material, which may be copper, aluminum, other thermally conductive material, alloys thereof, or combinations thereof. Support wick 65 may be a grooved wick, a sintered wick, a mesh wick, other wick type, or combinations thereof. In the depicted embodiment, support wick 65 is formed of copper and/or copper alloy, and a type of support wick 65 is different than a type of primary wick 40. For example, where primary wick 40 is a patterned copper structure (e.g., a copper grooved wick), support wick 65 may be a copper mesh wick or a copper sintered wick (e.g., formed of sintered copper powder). In some embodiments, support wick 65 is thermoformed on casing 50 (e.g., on inner wall/surface of lower plate 54 and/or along lower portions of sidewalls of support columns 62). In some embodiments, a process temperature of about 100° C. to about 200° C. may be used when forming support wick 65. In some embodiments, support wick 65 and primary wick 40 are a same type of wick. For example, support wick 65 and primary wick 40 may both be thermally conductive mesh wicks.

To provide a closed chamber (e.g., chamber 70), lateral dimensions of support wick 65 (e.g., a width and/or a length thereof) are greater than or equal to lateral dimensions of opening 58 (e.g., a width and/or a length thereof) in lower plate 54. Lateral dimensions of support wick 65 are also greater than or equal to lateral dimensions of primary wick 40 (e.g., a width and/or a length thereof). For example, support wick 65 has a width w5 that is greater than or equal to width w3 of opening 58 (i.e., width w5≥width w3) and greater than or equal to width w1 of primary wick 40 (i.e., width w5≥width w1). In the depicted embodiment, width w5 is greater than width w1. In some embodiments, a length of support wick 65 is also greater than length l1 of primary wick 40. Support wick 65 also has a thickness t2 that is less than about 500 μm (e.g., about 100 μm to about 500 μm). In some embodiments, thickness t2 is greater than thickness t1 of primary wick 40. In some embodiments, thickness t2 is less than thickness t1. In some embodiments, thickness t2 is substantially the same as thickness t1.

In FIG. 1A, lid assembly 20 is secured to die assembly 15 to provide package structure 10 (e.g., an IC package). Die 25 is disposed between lid assembly 15 and package component 30, and lid assembly 20 and package component 30 form a protective housing around and/or confining die 25. For example, lower plate 54 may be secured to package component 30 by an adhesive 80, mounting flanges 60 may be secured to package component 30 by an adhesive 82, and mounting flanges 60 may be secured to sidewalls of die 25 by an adhesive 84. In some embodiments, in a top view, mounting flanges 60 form a wall around a perimeter of die 25. In some embodiments, adhesive 84 is eliminated from package structure 10, and a gap and/or a spacing is between sidewalls of die 25 and mounting flanges 60 (i.e., mounting flanges 60 may not be directly or indirectly connected to die 25). Adhesive 80, adhesive 82, and adhesive 84 include any material suitable for securing and/or sealing lid assembly 20 to package component 30. In some embodiments, adhesive 80, adhesive 82, and adhesive 84 include a same material and/or a same composition. In some embodiments, adhesive between lid assembly 20 and die 25 (i.e., adhesive 84) and adhesive between lid assembly 20 and package component 30 (i.e., adhesive 80 and adhesive 82) include different materials and/or compositions.

In package structure 10, a die-mounted wick component (i.e., primary wick 40) and a lid-mounted wick component (i.e., support wick 65) combine to provide a wick structure, and the wick structure and casing 50 combine to provide a vapor chamber, such as chamber 70. Primary wick 40 is thermally coupled to support wick 65, and casing 50 (e.g., lower plate 54 thereof) is thermally coupled to die 25 by the wick structure (e.g., support wick 65 and primary wick 40). A hybrid vapor chamber lid (i.e., one having a die-mounted vapor chamber component, such as primary wick 40) is thus provided in thermal contact with die 25. In such configuration, die 25 is thermally coupled to lid assembly 20 via primary wick 40, instead of via a thermal interface material (TIM). In fact, TIM is not between lid assembly 20 and lid-facing side 26 of die 25. Accordingly, when assembled, a spacing s and/or a gap is between lid-facing side 26 of die 25 and lower plate 54. In some embodiments, lower plate 54 of casing 50 does not directly (e.g., physically) contact lid-facing side 26 of die 25. Eliminating TIM, which typically has a higher thermal conductivity than casing 50 and/or the wick structure, from between die 25 and lid assembly 20 reduces thermal resistance therebetween, thereby improving thermal conductivity between die 25 and the hybrid vapor chamber lid. Heat may thus be transferred from die 25 to lid assembly 20 through evaporation and condensation within chamber 70 more quickly than when TIM (and its corresponding thermal resistance) is between die 25 and lid assembly 20.

Chamber 70 may be hermetically sealed, and a working fluid 90 is contained within chamber 70. Working fluid 90 is a two-phase vaporizable fluid (e.g., a fluid that may change between a gas phase (e.g., a vapor phase) and a liquid phase). The two-phase vaporizable fluid may be water, ethanol, methanol, refrigerant (e.g., freon), other two-phase vaporizable fluid, or combinations thereof. In some embodiments, casing 50 and the wick structure are copper-containing components and working fluid 90 is water. Working fluid 90 may flow through primary wick 40 and/or support wick 65, and primary wick 40 and/or support wick 65 may convey working fluid 90 by capillary action. Primary wick 40 is fluidically coupled to support wick 65 and working fluid 90 may flow between primary wick 40 and support wick 65.

During operation of die 25, the hybrid vapor chamber lid may absorb heat from die 25 and/or transfer heat away from die 25 to a surrounding environment. For example, as die 25 generates heat, heat transfers from die 25 (e.g., lid-facing side 26 thereof) to the wick structure (e.g., primary wick 40 and/or support wick 65) to working fluid 90. As working fluid 90 in the wick structure absorbs heat from die 25 and a temperature of working fluid 90 in the wick structure increases, heated portions of working fluid 90 may transform from a liquid phase (e.g., a liquid) into a gas phase (e.g., a vapor) (i.e., working fluid 90 evaporates). Working fluid 90 in the gas phase (referred to as a vapor) may spread and/or move in chamber 70 from heated regions of lid assembly 20 (e.g., the wick structure and lower plate 54) to cooler regions of lid assembly 20 (e.g., upper plate 52, sidewalls 56, support columns 56, or combinations thereof). As the vapor contacts the cooler regions (e.g., inner surfaces of upper plate 52, inner surfaces of sidewalls 56, support columns 62, inner surfaces of peripheral regions of lower plate 54, or combinations thereof), a temperature of the vapor decreases as the cooler regions absorb heat from the vapor, and the vapor transforms back into the liquid phase (i.e., working fluid 90 condenses), flows to the wick structure, and flows back to the heat source (i.e., die 25) via capillary action/force of the wick structure. In such embodiments, the hybrid vapor chamber lid may be described as having an evaporator side 92 (e.g., formed at least by the wick structure and lower plate 54 of casing 50) and a condenser side 94 (e.g., formed by at least upper plate 52 of casing 50). As working fluid 90 cycles through evaporation, condensation, and capillary feedback, the hybrid vapor chamber lid efficiently draws heat away from die 25, thereby cooling die 25, and may transfer the heat to a surrounding environment. In some embodiments, such as depicted in FIG. 3, package structure 10 includes a heat sink 96, and the heat transfers from the hybrid vapor chamber lid to heat sink 96 and/or other heat removal component (e.g., a heat spreader) thermally coupled to lid assembly 20. In the depicted embodiment, heat sink 96 is disposed over and/or on outer surface/wall of upper plate 52. Heat sink 96 may be disposed directly on upper plate 52. Heat sink 96 is formed of a thermally conductive material that dissipates heat efficiently, such as copper, aluminum, alloys thereof (e.g., aluminum nitride), other highly thermally conductive material (e.g., silicon carbide), or combinations thereof.

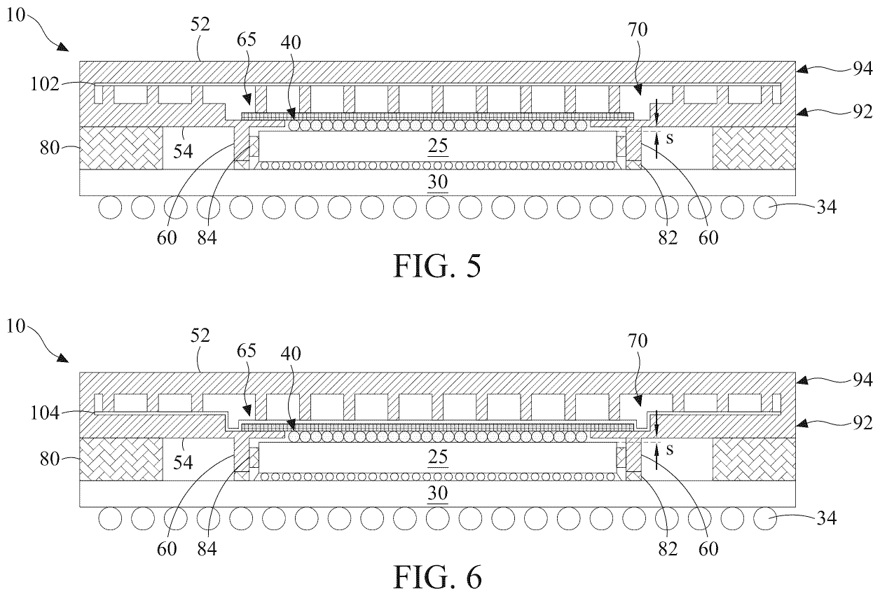

The present disclosure contemplates various configurations of primary wick 40, lid assembly 20, casing 50, upper plate 52, lower plate 54, sidewalls 56, opening 58, mounting flanges 60, support pillars 62, opening 64, support wick 65, chamber 70, working fluid 90, or combinations thereof to provide a hybrid vapor chamber lid as described herein. In some embodiments, such as depicted in FIG. 4, support wick 65 and primary wick 40 have substantially the same lateral dimensions. For example, width w5 is about equal to width w1, and the length of support wick 65 is about equal to length l1. In such embodiments, width w5 may be about equal to width w3 of opening 58, and support wick 65 may be disposed within lower plate 54, instead of on ledge 54L of lower plate 54. For example, in FIG. 4, lower plate 54 has a substantially uniform thickness (e.g., a thickness of peripheral portions of lower plate 54 are substantially the same as a thickness of a central portion of lower plate 54), and support wick 65 is not disposed over and/or on a ledge of lower plate 54. Instead, support wick 65 spans opening 58, and support wick 65 is secured between sidewalls and/or edges of lower plate 54 that form/define opening 58. Further, support wick 65 and primary wick 40 are disposed within opening 58 of lower plate 54. In some embodiments, lower plate 54 overlaps less than about 15% of die 25 (e.g., about 5% to about 15%). In some embodiments, such as depicted in FIGS. 1A-1C, FIG. 3, and FIG. 4, lower plate 54 overlaps peripheral portions of die 25.

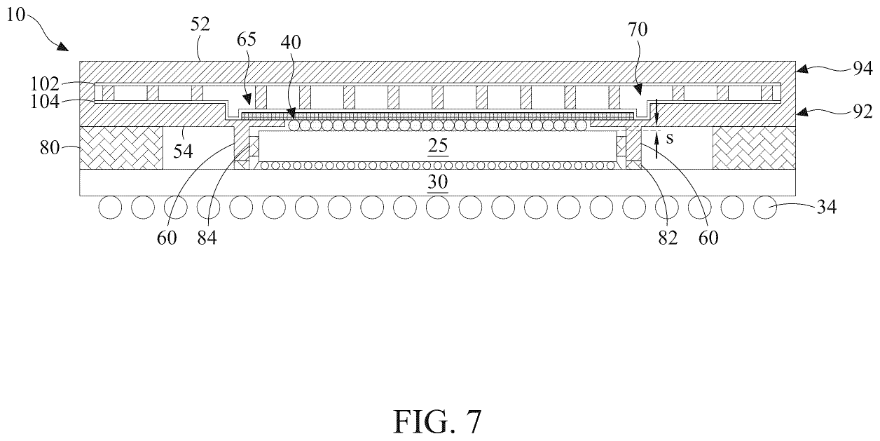

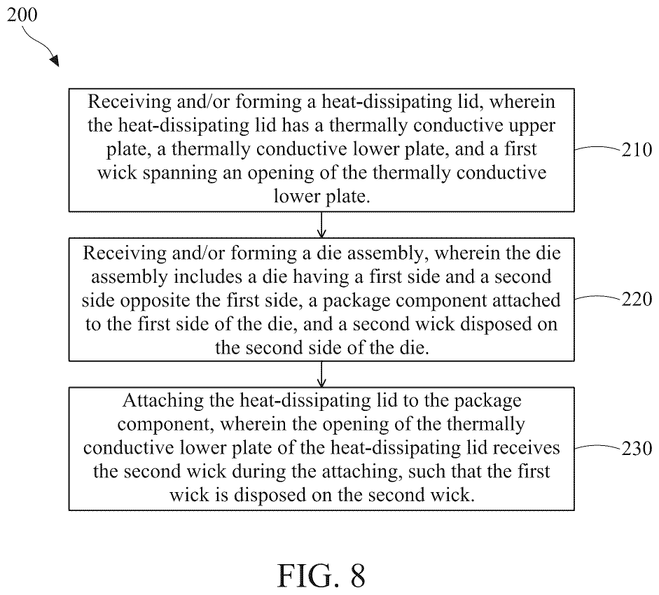

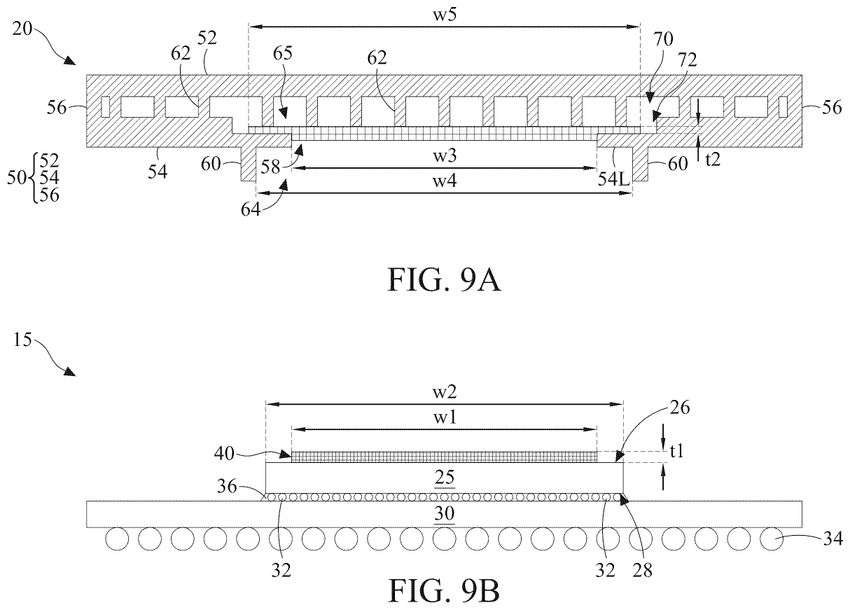

In some embodiments, additional thermally conductive layers may be incorporated into lid assembly 20. For example, such as depicted in FIG. 5, lid assembly 20 further includes a thermally conductive layer 102 disposed on and covering inner surface/wall of upper plate 52 of casing 50. In such embodiments, chamber 70 is enclosed by the wick structure (e.g., support wick 65 and primary wick 40), upper plate 52, lower plate 54, sidewalls 56, and thermally conductive layer 102. In another example, such as depicted in FIG. 6, lid assembly 20 further includes a thermally conductive layer 104 disposed on and covering inner surface/wall of lower plate 54 of casing 50. Thermally conductive layer 104 may further be disposed on and cover support wick 65. In such embodiments, chamber 70 is enclosed by the wick structure (e.g., support wick 65 and primary wick 40), upper plate 52, lower plate 54, sidewalls 56, and thermally conductive layer 104. In yet another example, such as depicted in FIG. 7, lid assembly 20 includes both thermally conductive layer 102 and thermally conductive layer 104. In such embodiments, chamber 70 is enclosed by the wick structure (e.g., support wick 65 and primary wick 40), upper plate 52, lower plate 54, sidewalls 56, thermally conductive layer 102, and thermally conductive layer 104. The present disclosure contemplates other configurations of thermally conductive layer 102 and/or thermally conductive layer 104, such as embodiments where thermally conductive layer 102 partially, instead of entirely, covers inner surface/wall of upper plate 52, embodiments where thermally conductive layer 104 partially, instead of entirely, covers inner surface/wall of lower plate 54, embodiments where thermally conductive layer 104 covers inner surface/wall of lower plate 54, but not support wick 65, embodiments where thermally conductive layer 104 partially, instead of entirely, covers support wick 65, embodiments where thermally conductive layer 104 covers support wick 65, but not inner surface/wall of lower plate 54, other configurations, or combinations thereof. In some embodiments, lid assembly 20 may further include a thermally conductive layer disposed along inner surfaces/walls of sidewalls 56. In some embodiments, lid assembly 20 may further include thermally conductive layers disposed along sidewalls of one or more support pillars 62.

Thermally conductive layer 102 and thermally conductive layer 104 each include a thermally conductive material, such as copper, aluminum, other material having high thermal conductivity, alloys thereof (e.g., copper tungsten (CuW), copper-silicon-carbide (CuSiC), aluminum-silicon-carbide (AlSiC), or combinations thereof), or combinations thereof. In some embodiments, thermally conductive layer 102 and thermally conductive layer 104 are formed of a same thermally conductive material. For example, thermally conductive layer 102 and thermally conductive layer 104 may be copper layers. In some embodiments, thermally conductive layer 102 and thermally conductive layer 104 are formed of different thermally conductive materials. In some embodiments, thermally conductive layer 102 is a copper mesh layer. In some embodiments, thermally conductive layer 104 is a copper mesh layer.

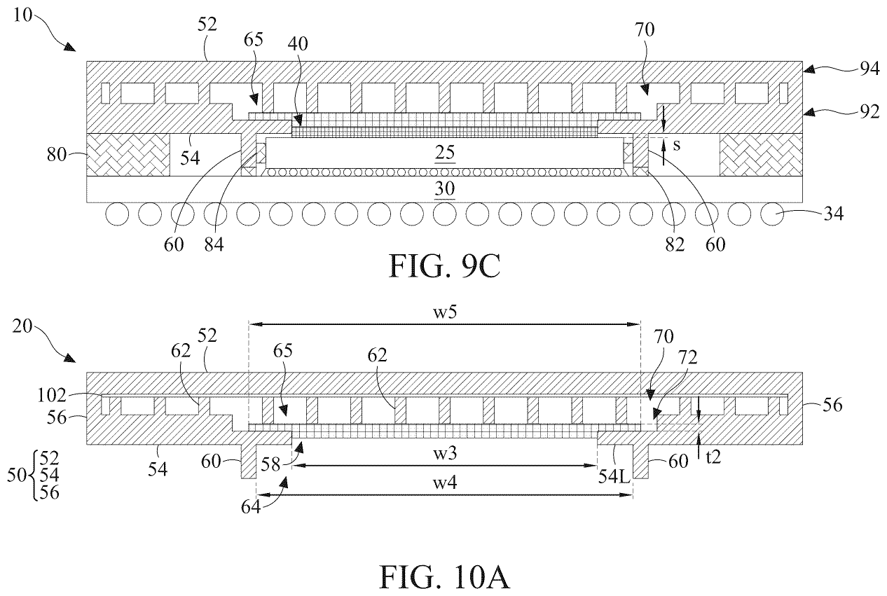

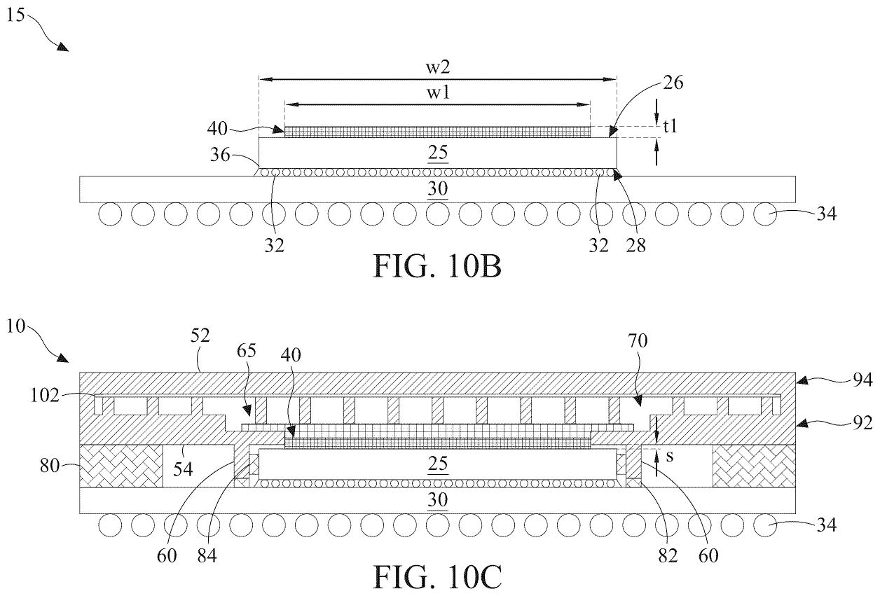

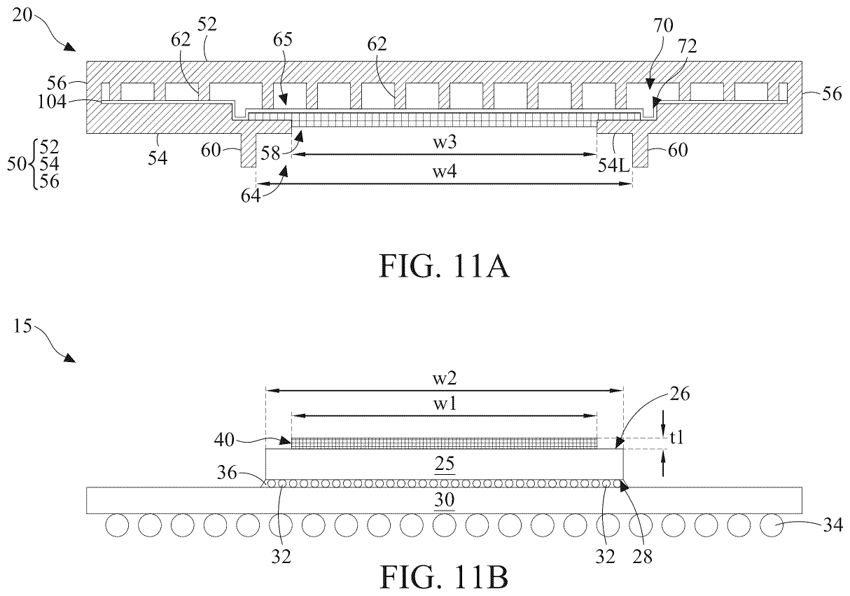

FIG. 8 is a flow chart of a method 200, in portion or entirety, for assembling and/or forming a package structure having a hybrid vapor chamber lid, such as package structure 100, according to various aspects of the present disclosure. FIGS. 9A-9C are cross-sectional views of package structure 100, in portion or entirety, at various stages of method 200, according to various aspects of the present disclosure. FIGS. 10A-10C, FIGS. 11A-11C, and FIGS. 12A-12C are cross-sectional views of alternative embodiments of package structure 100, in portion or entirety, at various stages of method 200, according to various aspects of the present disclosure. FIG. 8, FIGS. 9A-9C, FIGS. 10A-10C, FIGS. 11A-11C, and FIGS. 12A-12C are discussed concurrently herein for ease of description and have been simplified for the sake of clarity to better understand the inventive concepts of the present disclosure. Additional steps may be provided before, during, and after method 200, and some of the steps described may be moved, replaced, or eliminated for additional embodiments of method 200.

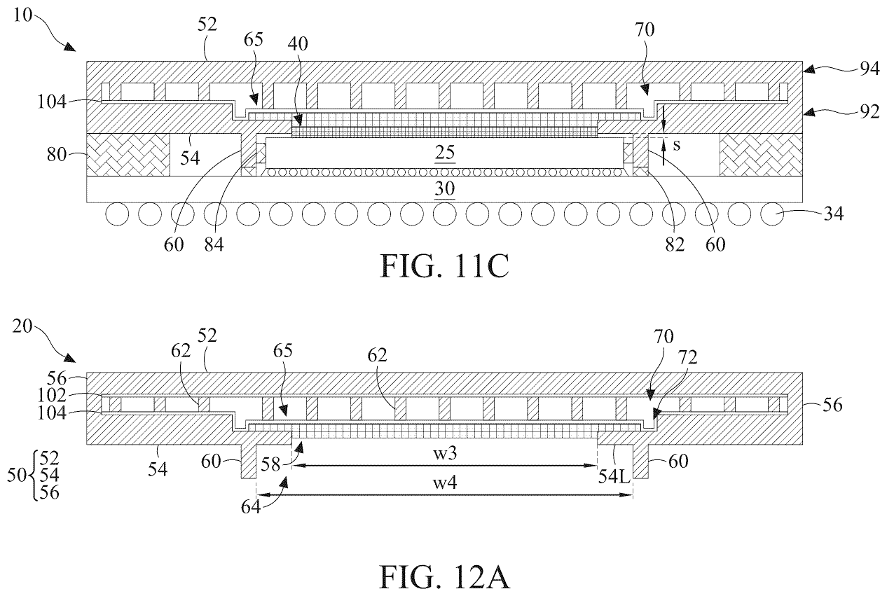

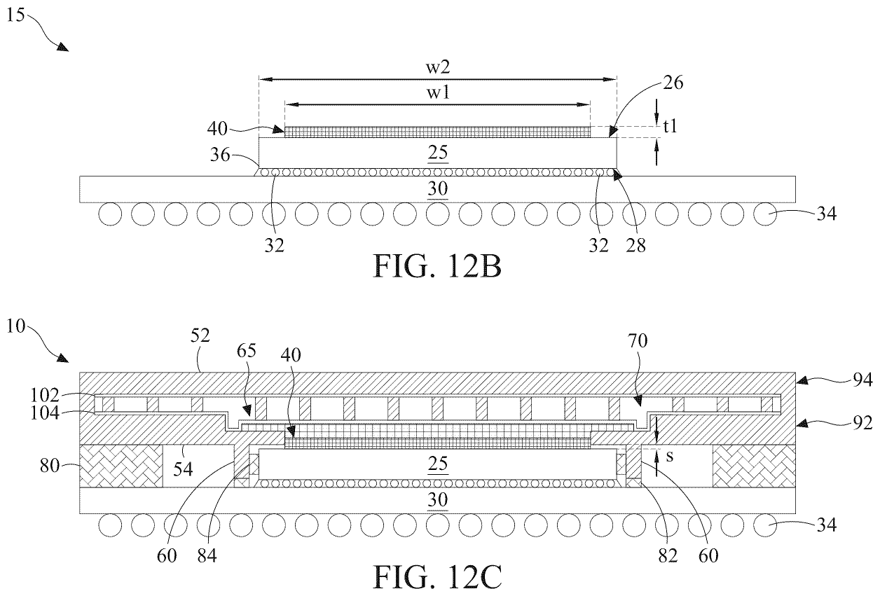

Referring to FIG. 8 and FIG. 9A, method 200 may include receiving and/or forming a heat-dissipating lid, such as lid assembly 20, at block 210. The heat-dissipating lid has a thermally conductive upper plate (e.g., upper plate 52), a thermally conductive lower plate (e.g., lower plate 54), and a first wick (e.g., support wick 65) spanning an opening (e.g., opening 58) of the thermally conductive lower plate. In some embodiments, the first wick is disposed within the opening of the thermally conductive lower plate. In some embodiments, forming heat-dissipating lid includes forming the first wick on the thermally conductive lower plate. Forming the first wick may include thermoforming a copper mesh wick and/or a copper sintered wick on the thermally conductive lower plate. In some embodiments, such as depicted in FIG. 10A, forming the heat-dissipating lid includes forming a thermally conductive layer (e.g., thermally conductive layer 102) on an inner surface/wall of the thermally conductive upper plate. In some embodiments, such as depicted in FIG. 11A, forming the heat-dissipating lid includes forming a thermally conductive layer (e.g., thermally conductive layer 104) on an inner surface/wall of the thermally conductive lower plate. The thermally conductive layer may also be formed on the first wick. In some embodiments, such as depicted in FIG. 12A, forming the heat-dissipating lid includes forming thermally conductive layers (e.g., thermally conductive layer 102 and thermally conductive layer 104) on both the inner surface/wall of the thermally conductive upper plate and the inner surface/wall of the thermally conductive lower plate.

Referring to FIG. 8, FIG. 9B, FIG. 10B, FIG. 11B, and FIG. 12B, method 200 may include receiving and/or forming a die assembly, such as die assembly 15, at block 220. The die assembly includes a die (e.g., die 25) having a first side (e.g., lid-facing side 26) and a second side (e.g., side 28) opposite the first side. The die assembly further includes a package component (e.g., package component 30) attached to the first side of the die. The die assembly further includes a second wick, such as primary wick 40, disposed on the second side of the die. In some embodiments, forming the die assembly includes attaching and/or bonding the die to the package component. In some embodiments, forming the die assembly includes forming the second wick on the first side of the die. The second wick is formed on the die before attaching the heat-dissipating lid to the die assembly, and the first wick is formed on the heat-dissipating lid before attaching the heat-dissipating lid to the die assembly. The second wick may be formed before or after attaching and/or bonding the die to the package component. Forming the second wick may include forming a patterned copper structure (e.g., a copper grooved wick) on the first side of the die. Forming the patterned copper structure may include depositing a copper-containing material (e.g., by PVD and/or CVD) on the first side of the die.

Referring to FIG. 8, FIG. 9C, FIG. 10C, FIG. 11C, and FIG. 12C, method 200 may include attaching the heat-dissipating lid (e.g., lid assembly 20) to the package component (e.g., package component 30) at block 230. During the attaching, the opening of the thermally conductive lower plate of the heat-dissipating lid receives the second wick, such that the first wick is disposed on the second wick. The attaching may include aligning the heat-dissipating lid with the die assembly, such that the second wick may be pressed through and/or into the opening of the thermally conductive lower plate of the heat-dissipating lid and the die may be pressed through and/or into an opening of the heat-dissipating lid (e.g., opening 64 formed by mounting flanges 60). In some embodiments, attaching the heat-dissipating lid (e.g., lid assembly 20) to the package component includes forming adhesive (e.g., adhesive 80 and/or adhesive 82) on the heat-dissipating lid (e.g., on lower plate 54 and/or on mounting flanges 60) and/or on package component 30 and pressing the heat-dissipating lid and package component into one another to effectuate attachment. In some embodiments, adhesive (e.g., adhesive 84) may be formed between the heat-dissipating lid (e.g., mounting flanges 60) and the die (e.g., die 25).

The present disclosure provides for many different embodiments. An exemplary heat-dissipating lid includes a thermally conductive casing having an upper plate and a lower plate, a first wick structure disposed on the lower plate and spanning an opening of the lower plate, and a hollow interior region disposed within the thermally conductive casing between the upper plate and the lower plate and between the upper plate and the first wick structure. The opening of the lower plate is configured to receive a second wick structure that is disposed on an integrated circuit (IC) die. In some embodiments, the heat-dissipating lid further includes thermally conductive columns disposed in the hollow interior region and between the upper plate and the lower plate. In some embodiments, the opening is a first opening, the thermally conductive casing further has mounting flanges extending from the lower plate, and the mounting flanges define a second opening for receiving the IC die.

In some embodiments, a first lateral dimension of the opening is less than a second lateral dimension of the IC die. In some embodiments, a first lateral dimension of the first wick structure is different than a second lateral dimension of the second wick structure. In some embodiments, a first type of the first wick structure is different than a second type of the second wick structure. In some embodiments, the heat-dissipating lid further includes a thermally conductive layer disposed over an inner surface of the upper plate that defines the hollow interior region. In some embodiments, the heat-dissipating lid further includes a thermally conductive layer disposed over an inner surface of the lower plate that defines the hollow interior region. In some embodiments, the heat-dissipating lid further includes a thermally conductive layer disposed over an inner surface of the upper plate that defines the hollow interior region and a thermally conductive layer disposed over an inner surface of the lower plate that defines the hollow interior region. In some embodiments, the thermally conductive casing further has sidewall plates that extend between the lower plate and the upper plate.

An exemplary package structure includes a package component (e.g., a package substrate, an interposer, or a printed circuit board), a die, a lid, and a wick structure. The die has a first side and a second side opposite the first side, and the first side of the die is attached to the package component. The die is disposed between the lid and the package component. The lid is attached to the package component, and the lid and the package component form a housing around the die. The wick structure thermally couples the die to the lid. The wick structure and the lid enclose a chamber filled with vaporizing fluid. The wick structure includes a primary wick and a support wick. The primary wick is disposed on the second side of the die and within an opening of a thermally conductive bottom plate of the lid. The support wick is disposed on the lid, over the primary wick, and spanning the opening of the thermally conductive bottom plate of the lid. The support wick is fluidically coupled to the primary wick.

In some embodiments, the package structure is free of a thermal interface material between the lid and the die. In some embodiments, the second side of the die is separated from the thermally conductive bottom plate of the lid by a spacing. In some embodiments, the primary wick is a first type and the support wick is a second type different than the first type. In some embodiments, the primary wick covers at least 85% of the second side of the die. In some embodiments, the chamber is enclosed by a thermally conductive top plate of the lid, the thermally conductive bottom plate of the lid, and the wick structure. In some embodiments, a first thermally conductive metal layer may be disposed within the chamber and on the thermally conductive bottom plate of the lid, and a second thermally conductive metal layer may be disposed within the chamber and on the thermally conductive top plate of the lid.

In some embodiments, the die is a system-on-chip. In some embodiments, the first side is a frontside, the second side is a backside, and the backside of the die is electrically connected to the package component. In some embodiments, the package structure further includes a heat sink disposed over a thermally conductive top plate of the lid.

An exemplary method includes receiving a heat-dissipating lid, receiving a die assembly, and attaching the heat-dissipating lid to the package component. The heat-dissipating lid has a thermally conductive upper plate, a thermally conductive lower plate, and a first wick structure spanning an opening of the thermally conductive lower plate. The die assembly includes a die having a first side and a second side opposite the first side, a package component attached to the first side of the die, and a second wick structure disposed on the second side of the die. The opening of the thermally conductive lower plate of the heat-dissipating lid receives the second wick structure during the attaching, such that the first wick structure is disposed on the second wick structure. A spacing may be between the second side of the die and the thermally conductive lower plate of the heat-dissipating lid. In some embodiments, the method further includes attaching the heat-dissipating lid to sidewalls of the die.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A heat-dissipating lid comprising:
a thermally conductive casing having an upper plate and a lower plate;
a first wick structure disposed on the lower plate and spanning an opening of the lower plate, wherein the opening of the lower plate is configured to receive a second wick structure that is disposed on an integrated circuit (IC) die; and
a hollow interior region disposed within the thermally conductive casing between the upper plate and the lower plate and between the upper plate and the first wick structure.

2. The heat-dissipating lid of claim 1, wherein a first lateral dimension of the opening is less than a second lateral dimension of the IC die.

3. The heat-dissipating lid of claim 1, further comprising a thermally conductive layer disposed over an inner surface of the upper plate that defines the hollow interior region.

4. The heat-dissipating lid of claim 1, further comprising a thermally conductive layer disposed over an inner surface of the lower plate that defines the hollow interior region.

5. The heat-dissipating lid of claim 4, wherein the thermally conductive layer is further disposed over an inner surface of the upper plate that defines the hollow interior region.

6. The heat-dissipating lid of claim 1, wherein a first lateral dimension of the first wick structure is different than a second lateral dimension of the second wick structure.

7. The heat-dissipating lid of claim 1, wherein a first type of the first wick structure is different than a second type of the second wick structure.

8. The heat-dissipating lid of claim 1, further comprising thermally conductive columns disposed in the hollow interior region and between the upper plate and the lower plate.

9. The heat-dissipating lid of claim 1, wherein:
the opening is a first opening; and
the thermally conductive casing further has mounting flanges extending from the lower plate, wherein the mounting flanges define a second opening for receiving the IC die.

10. A package structure comprising:
a package component;
a die having a first side and a second side opposite the first side, wherein the first side of the die is attached to the package component;
a lid attached to the package component, wherein the lid and the package component form a housing around the die and the die is disposed between the lid and the package component; and
a wick structure that thermally couples the die to the lid, wherein the wick structure and the lid enclose a chamber filled with vaporizing fluid, wherein the wick structure includes:
a primary wick disposed on the second side of the die and within an opening of a thermally conductive bottom plate of the lid, and
a support wick disposed on the lid, over the primary wick, and spanning the opening of the thermally conductive bottom plate of the lid, wherein the support wick is fluidically coupled to the primary wick.

11. The package structure of claim 10, wherein the package structure is free of a thermal interface material between the lid and the die.

12. The package structure of claim 10, wherein the second side of the die is separated from the thermally conductive bottom plate of the lid by a spacing.

13. The package structure of claim 10, wherein the primary wick is a first type and the support wick is a second type different than the first type.

14. The package structure of claim 10, wherein the primary wick covers at least 85% of the second side of the die.

15. The package structure of claim 10, wherein:
the chamber is enclosed by a thermally conductive top plate of the lid, the thermally conductive bottom plate of the lid, and the wick structure;
a first thermally conductive metal layer is disposed within the chamber and on the thermally conductive bottom plate of the lid; and
a second thermally conductive metal layer is disposed within the chamber and on the thermally conductive top plate of the lid.

16. The package structure of claim 10, wherein the die is a system-on-chip.

17. The package structure of claim 10, wherein the first side is a frontside, the second side is a backside, and the backside of the die is electrically connected to the package component.

18. The package structure of claim 10, further comprising a heat sink disposed over a thermally conductive top plate of the lid.

19. A method comprising:
receiving a heat-dissipating lid, wherein the heat-dissipating lid has a thermally conductive upper plate, a thermally conductive lower plate, and a first wick structure spanning an opening of the thermally conductive lower plate;
receiving a die assembly, wherein the die assembly includes a die having a first side and a second side opposite the first side, a package component attached to the first side of the die, and a second wick structure disposed on the second side of the die; and
attaching the heat-dissipating lid to the package component, wherein the opening of the thermally conductive lower plate of the heat-dissipating lid receives the second wick structure during the attaching, such that the first wick structure is disposed on the second wick structure.

20. The method of claim 19, further comprising attaching the heat-dissipating lid to sidewalls of the die, wherein a spacing is between the second side of the die and the thermally conductive lower plate of the heat-dissipating lid.
